(19) United States
(12) Patent Application Publication
(10) Pub. No.: US 2026/0362875 A1
(43) Pub. Date: Nov. 12, 2026

(54) OPTICAL TRANSMISSION DEVICE

(71) Applicant: National Chung Hsing University, Taichung City (TW)

(72) Inventor: CHIA-FENG LIN, Taichung City (TW)

(73) Assignee: National Chung Hsing University, Taichung City (TW)

(21) Appl. No.: 19/205,952

(22) Filed: May 12, 2025

(51) Int. Cl. H10H 29/24; H10H 29/85; H10H 29/856

(52) U.S. Cl. CPC H10H 29/24; H10H 29/856; H10H 29/857

(57) ABSTRACT

An optical transmission device includes a driving element and an optical transmission element. The optical transmission element includes a substrate and a plurality of optical transmission module. A lateral reference line perpendicular to a longitudinal reference line is defined. The optical transmission modules are spaced apart, arranged along the longitudinal reference line, and formed above the substrate. Each optical transmission module includes a first reflective layer located above the substrate, a light-emitting diode layer formed above the first reflective layer, and a second reflective layer formed above the light-emitting diode layer. An emission area, an optical guide area, and an optical detection area are sequentially arranged along a direction of the lateral reference line, each including the first reflective layer, the light-emitting diode layer, and the second reflective layer. The driving element drives the emission area of each optical transmission module.

### BACKGROUND OF THE INVENTION

### Technical Field

The present invention relates to optical communication, and more particularly to an optical transmission device capable of reducing optical loss.

### Description of Related Art

It is known that with the continuous growth in data transmission demands, traditional copper wire and optical fiber technologies have gradually revealed their limitations, such as low transmission efficiency and high structural costs. Therefore, optical communication technology has been widely applied as a replacement for traditional copper wire or optical fiber transmission.

Generally, an optical transmission device transmits an optical signal into an optical fiber by coupling one end of the optical fiber to a light source of a light-emitting diode (LED), for example. The other end of the optical fiber is coupled to a photodiode (PD), for example, to detect the optical signal. However, during signal transmission, optical loss tends to occur at an interface between the optical fiber and the light-emitting diode, or at an interface between the optical fiber and the photodiode. Accordingly, providing an optical transmission device capable of reducing such optical loss remains an urgent issue to be addressed.

### BRIEF SUMMARY OF THE INVENTION

In view of the above, the primary objective of the present invention is to provide an optical transmission device capable of reducing optical loss.

The present invention provides an optical transmission device including a driving element and an optical transmission element. The optical transmission element includes a substrate and a plurality of optical transmission modules. A longitudinal reference line is defined, wherein the optical transmission modules are spaced apart and arranged along a direction of the longitudinal reference line. The optical transmission modules are formed above the substrate. Each optical transmission module includes a first reflective layer located above the substrate, a light-emitting diode layer formed above the first reflective layer, and a second reflective layer formed above the light-emitting diode layer. A lateral reference line perpendicular to the longitudinal reference line is defined. An emission area, an optical guide area, and an optical detection area are defined as being arranged sequentially along a direction of the lateral reference line. Each of the emission area, the optical guide area, and the optical detection area includes the first reflective layer, the light-emitting diode layer, and the second reflective layer. The driving element is electrically connected to each optical transmission module to drive the emission area of each optical transmission module.

Through the design in which the first reflective layer, the light-emitting diode layer, and the second reflective layer of the emission area, the optical guide area, and the optical detection area are formed continuously without any interface between them, the light emitted by the emission area of each optical transmission module could be reflected between the first reflective layer and the second reflective layer of each optical transmission module, and guided by the optical guide area to the optical detection area of each optical transmission module. In this way, optical loss generated during light transmission could be effectively reduced.

### BRIEF DESCRIPTION OF THE SEVERAL VIEWS OF THE DRAWINGS

The present invention would be best understood by referring to the following detailed description of some illustrative embodiments in conjunction with the accompanying drawings, in which

FIG. 1 is a schematic view of the optical transmission device according to an embodiment of the present invention;

FIG. 2 is a sectional view of the emission area along the A-A line in FIG. 1;

FIG. 3 is a sectional view along the B-B line in FIG. 1;

FIG. 4 is a schematic view of the optical transmission device according to the embodiment of the present invention, showing an application of the optical transmission device.

### DETAILED DESCRIPTION OF THE INVENTION

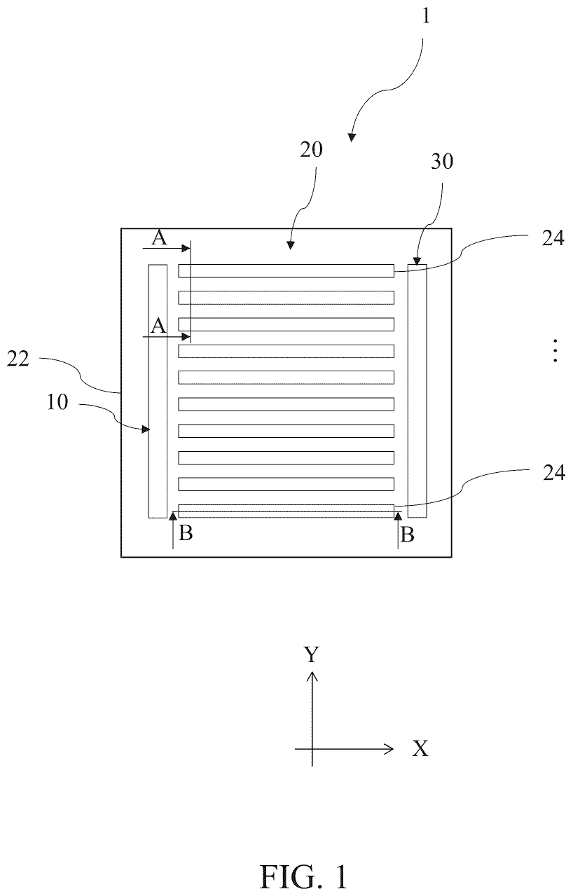

An optical transmission device 1 according to an embodiment of the present invention is illustrated in FIG. 1 to FIG. 4 and includes a driving element 10, an optical transmission element 20, and a power element 30.

As shown in FIG. 1, the optical transmission element 20 includes a substrate 22 and a plurality of optical transmission modules 24. A lateral reference line X and a longitudinal reference line Y, which are perpendicular to each other, are defined. The optical transmission modules 24 are spaced apart and arranged along a direction of the longitudinal reference line Y. The optical transmission modules 24 are formed above the substrate 22. The substrate 22, for example, might be a sapphire substrate, a silicon substrate, a silicon carbide substrate, a gallium arsenide substrate, an indium phosphide substrate, or a glass substrate.

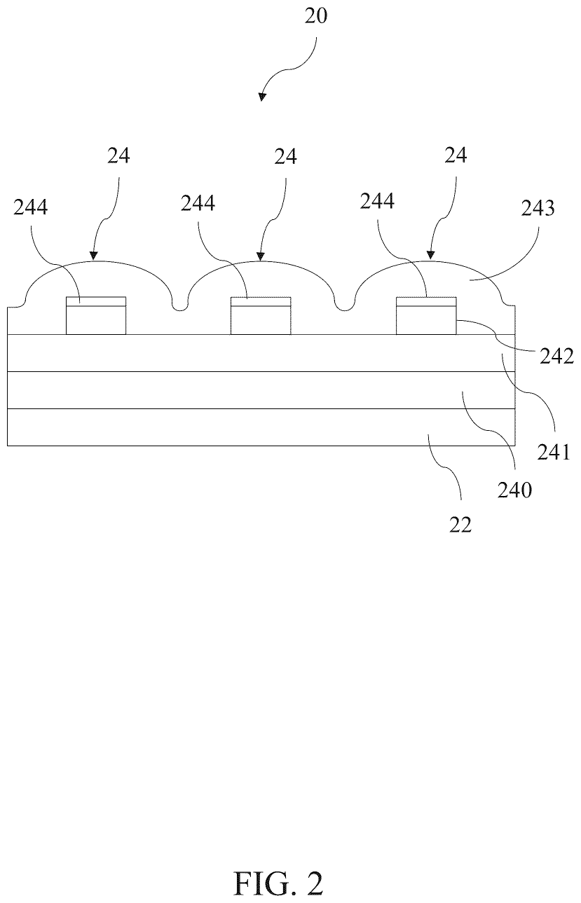

As shown in FIG. 2, the optical transmission element 20 includes a buffer layer 240, a first reflective layer 241, a light-emitting diode layer 242, and a second reflective layer 243, which are stacked on one another. Each optical transmission module 24 includes the first reflective layer 241, the light-emitting diode layer 242, and the second reflective layer 243. The first reflective layer 241 is conductive, and the buffer layer 240 is formed above the substrate 22. Each optical transmission module 24 is formed above the buffer layer 240. The buffer layer 240, for example, might be an undoped GaN layer. The first reflective layer 241 is formed on the buffer layer 240 and is located above the substrate 22. The first reflective layer 241 is a porous reflective layer or a pipe reflective layer. For example, the first reflective layer 241 might be a distributed Bragg reflector (DBR), and the first reflective layer 241 is the porous reflective layer formed through wet electrochemical etching.

The light-emitting diode layer 242 is formed above the first reflective layer 241. The light-emitting diode layer 242, for example, could include an N-type AlInGaN sublayer doped with silicon, an InGaN light-emitting sublayer, and a P-type AlInGaN sublayer doped with magnesium, which are stacked on one another. In another embodiment, the light-emitting diode layer 242 could include a blue light diode structure, a green light diode structure, and a red light diode structure, which are vertically stacked on one another. The blue light diode structure is able to emit blue light, the green light diode structure is able to emit green light, and the red light diode structure is able to emit red light.

The second reflective layer 243 is formed above the light-emitting diode layer 242. The second reflective layer 243 covers a top portion and a side portion of the light-emitting diode layer 242. The second reflective layer 243 might be a SiO₂/TiO₂ dielectric distributed Bragg reflector or a dielectric/metal/dielectric reflector. In the current embodiment, a transparent conductive layer 244 is deposited between the second reflective layer 243 and the light-emitting diode layer 242. For example, the transparent conductive layer 244 might be an Indium Tin oxides (ITO) layer disposed between the light-emitting diode layer 242 and an electrode.

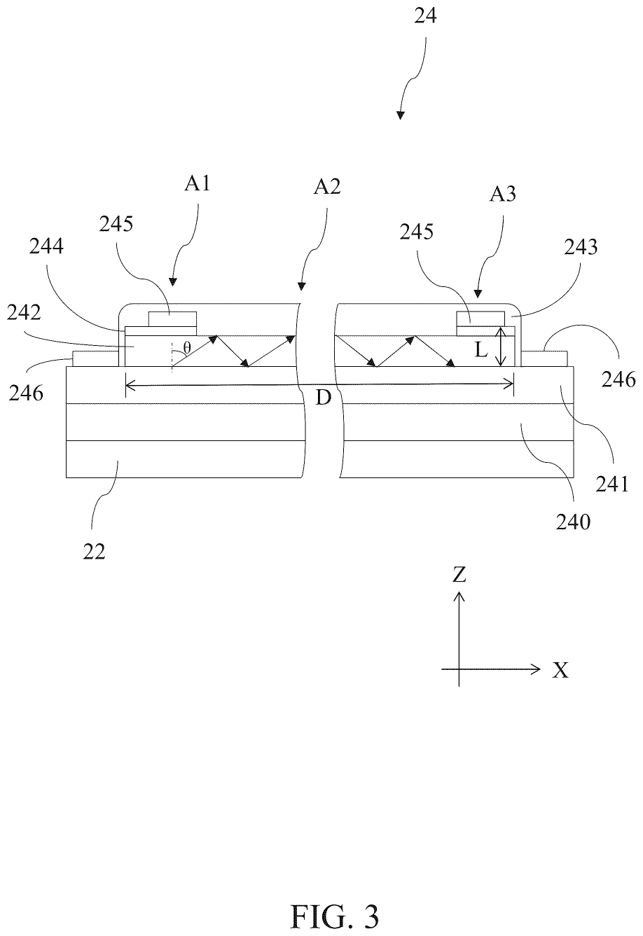

As shown in FIG. 3, an emission area A1, an optical guide area A2, and an optical detection area A3 are defined as being arranged sequentially along a direction of the lateral reference line X. Each of the emission area A1, the optical guide area A2, and the optical detection area A3 includes the first reflective layer 241, the light-emitting diode layer 242, and the second reflective layer 243. The emission area A1 includes a micro resonant-cavity light-emitting source (μ-RC-LED), and the optical detection area A3 includes a micro resonant-cavity photodetector element (μ-RC-PD). The optical guide area A2 has a length D along the direction of the lateral reference line X, wherein the length D is greater than or equal to 200 μm and less than or equal to 30 cm. A P-type electrode 245 is respectively disposed above the transparent conductive layer 244 of the emission area A1 and the transparent conductive layer 244 of the optical detection area A3. The N-type GaN sublayer doped with silicon of the emission area A1 and the N-type GaN sublayer doped with silicon of the optical detection area A3 are respectively electrically connected to an N-type electrode 246.

Through semiconductor processing, the buffer layer 240, the first reflective layer 241, the light-emitting diode layer 242, and the second reflective layer 243 could be formed above the substrate 22, and the optical transmission modules 24 arranged in an array are then defined. Therefore, light emitted from the light-emitting diode layer 242 of the emission area A1 is reflected between the first reflective layer 241 and the second reflective layer 243, and guided through the optical guide area A2 to the optical detection area A3. Through the design in which the first reflective layer 241, the light-emitting diode layer 242, and the second reflective layer 243 of the emission area A1, the optical guide area A2, and the optical detection area A3 are formed continuously without any interface between them, optical loss during the guiding of light through the optical guide area A2 from the light-emitting diode layer 242 of the emission area A1 to the optical detection area A3 could be significantly reduced. In the current embodiment, the plurality of optical transmission modules 24 are used as an example. In other embodiments, the optical transmission module 24 might also be one, and the single optical transmission module 24 could also achieve the same effect of guiding the light emitted from the light-emitting diode layer 242 of the emission area A1 through the optical guide area A2 to the optical detection area A3.

The driving element 10 is electrically connected to each optical transmission module 24 to drive the emission area A1 of each optical transmission module 24. The power element 30 is electrically connected to each optical transmission module 24 to receive a signal output from each optical transmission module 24. For example, the power element 30 might include an amplifier circuit element. Moreover, in the current embodiment, the driving element 10 and the power element 30 are formed on the substrate 22 through a semiconductor process. In other embodiments, the driving element 10 and the power element 30 are packaging bonded on the substrate 22 through a semiconductor process. An input signal of the driving element 10 is I/O signal, and an output signal of the power element 30 is also I/O signal. In this way, the driving element 10, the optical transmission modules 24, and the power element 30 could be formed on the substrate 22 within a single semiconductor process. In other embodiments, the optical transmission device 1 could also include a monocrystalline substrate. The driving element 10, the optical transmission element 20, and the power element 30 are individually fabricated and then disposed on the monocrystalline substrate, for example, using flip-chip packaging. The monocrystalline substrate might be a sapphire substrate, a silicon substrate, a silicon carbide substrate, a gallium arsenide substrate, an indium phosphide substrate, or a glass substrate. In other embodiments, the optical transmission device 1 could further include an additional driving element and an additional power element. The additional driving element is electrically connected to each optical transmission module 24 to drive the optical detection area A3 of each optical transmission module 24. The additional power element is electrically connected to each optical transmission module 24 to receive a signal output from each optical transmission module 24. In this way, each optical transmission module 24 could perform bidirectional optical signal transmission simultaneously. The emission area A1 and the optical detection area A3 have the same structure, which could act as a light-emitting diode under an electrical forward bias condition and as a photodetector under an electrical reverse bias condition, enabling bidirectional optical transmission.

Moreover, a vertical reference line Z which is perpendicular to the lateral reference line X and the longitudinal reference line Y is defined. The light emitted from the light-emitting diode layer 242 of the emission area A1 has a wavelength λ. A minimum distance L between the first reflective layer 241 and the second reflective layer 243 along the vertical reference line Z satisfies a condition of NL<3λ, wherein N is an optical refractive index of the light-emitting diode layer 242. A vertical optical resonant cavity might be formed between the first reflective layer 241 of the emission area A1 and the second reflective layer 243 of the emission area A1. Moreover, the light emitted from the light-emitting diode layer 242 of the emission area A1 has the wavelength λ, and the minimum distance L between the first reflective layer 241 and the second reflective layer 243 along the vertical reference line Z satisfies a condition of NL≠an integer multiple of nλ/2, wherein n is an integer and N is the optical refractive index of the light-emitting diode layer 242. In this way, as shown in FIG. 3, an angle θ is provided between the light emitted by the light-emitting diode layer 242 of the emission area A1 and the vertical reference line Z. The angle θ is greater than 0°, thereby facilitating the propagation of the light emitted by the light-emitting diode layer 242 of the emission area A1 within the optical guide area A2.

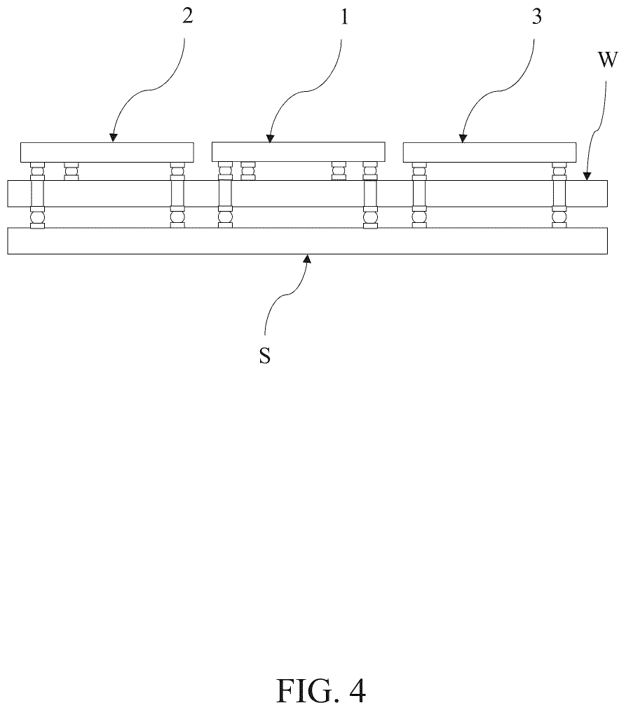

As shown in FIG. 4, for example, the CoWoS (Chip-on-Wafer-on-Substrate) packaging technology could be used to attach a processor chip 2, such as a GPU, CPU, NPU (XPU), a chip of the optical transmission device 1, and a high-bandwidth memory chip 3, such as HBM, onto a wafer W (e.g., an intermediate board, an interposer, or an ABF substrate), forming a Chip-On-Wafer (CoW) structure. The Chip-On-Wafer (CoW) structure is then attached to a substrate, such as a printed circuit board (PCB), thereby forming a CoWoS structure. In this way, the micro resonant-cavity light-emitting source (μ-RC-LED) of the emission area A1 could be connected to the processor chip 2 through the driving element 10. The micro resonant-cavity photodetector element (μ-RC-PD) of the optical detection area A3 could be connected to the high-bandwidth memory chip 3 through the power element 30. Thus, a complete signal input and output structure is achieved.

In summary, through the design in which the first reflective layer 241, the light-emitting diode layer 242, and the second reflective layer 243 of the emission area A1, the optical guide area A2, and the optical detection area A3 are formed continuously without any interface between them, the light emitted by the emission area A1 of each optical transmission module 24 could be reflected between the first reflective layer 241 and the second reflective layer 243 of each optical transmission module 24, and guided by the optical guide area A2 to the optical detection area A3 of each optical transmission module 24. In this way, optical loss generated during light transmission could be effectively reduced.

It must be pointed out that the embodiments described above are only some preferred embodiments of the present invention. All equivalent structures which employ the concepts disclosed in this specification and the appended claims should fall within the scope of the present invention.

What is claimed is:

1. An optical transmission device, comprising:
a driving element; and
an optical transmission element comprising a substrate and a plurality of optical transmission modules; a longitudinal reference line is defined, wherein the optical transmission modules are spaced apart and arranged along a direction of the longitudinal reference line; the optical transmission modules are formed above the substrate; Each optical transmission module comprises a first reflective layer located above the substrate, a light-emitting diode layer formed above the first reflective layer, and a second reflective layer formed above the light-emitting diode layer;
wherein a lateral reference line perpendicular to the longitudinal reference line is defined; an emission area, an optical guide area, and an optical detection area are defined as being arranged sequentially along a direction of the lateral reference line; each of the emission area, the optical guide area, and the optical detection area comprises the first reflective layer, the light-emitting diode layer, and the second reflective layer; the driving element is electrically connected to each optical transmission module to drive the emission area of each optical transmission module.

2. The optical transmission device as claimed in claim 1, further comprising a monocrystalline substrate; the driving element and the optical transmission element are disposed on the monocrystalline substrate using flip-chip packaging; the monocrystalline substrate is a sapphire substrate, a silicon substrate, a silicon carbide substrate, a gallium arsenide substrate, an indium phosphide substrate, or a glass substrate.

3. The optical transmission device as claimed in claim 2, further comprising a power element; the power element is electrically connected to each optical transmission module to receive a signal output from each optical transmission module; the power element is disposed on the monocrystalline substrate using flip-chip packaging.

4. The optical transmission device as claimed in claim 1, wherein the driving element is formed on the substrate.

5. The optical transmission device as claimed in claim 4, further comprising a power element; the power element is electrically connected to each optical transmission module to receive a signal output from each optical transmission module; the power element is formed on the substrate; the optical transmission device further comprises an additional driving element and an additional power element; the additional driving element is electrically connected to each optical transmission module, and the additional power element is electrically connected to each optical transmission module, such that each optical transmission module performs bidirectional optical signal transmission simultaneously.

6. The optical transmission device as claimed in claim 1, wherein the optical guide area has a length along the direction of the lateral reference line; the length is greater than or equal to 200 μm and less than or equal to 30 cm.

7. The optical transmission device as claimed in claim 1, wherein a vertical reference line which is perpendicular to the lateral reference line and the longitudinal reference line is defined; light emitted from the light-emitting diode layer of the emission area has a wavelength λ, and a minimum distance L between the first reflective layer and the second reflective layer along the vertical reference line satisfies a condition of NL≠an integer multiple of nλ/2, wherein n is an integer and N is an optical refractive index of the light-emitting diode layer.

8. The optical transmission device as claimed in claim 1, wherein a vertical reference line which is perpendicular to the lateral reference line and the longitudinal reference line is defined; light emitted from the light-emitting diode layer of the emission area has a wavelength λ, and a minimum distance L between the first reflective layer and the second reflective layer along the vertical reference line satisfies a condition of NL<3λ, wherein N is an optical refractive index of the light-emitting diode layer.

9. The optical transmission device as claimed in claim 1, wherein the first reflective layer is a porous reflective layer or a pipe reflective layer.

10. The optical transmission device as claimed in claim 1, wherein the substrate is a sapphire substrate, a silicon substrate, a silicon carbide substrate, a gallium arsenide substrate, or an indium phosphide substrate.
